(19) United States
(12) Patent Application Publication
(10) Pub. No.: US 2004/0152315 A1
(43) Pub. Date: Aug. 5, 2004

(54) Apparatus and method for manufacturing a semiconductor

(76) Inventor: Sang-Hun Oh, Kyungki-do (KR)

Correspondence Address: GROSSMAN & FLIGHT LLC, Suite 4220, 20 North Wacker Drive, Chicago, IL, 60606-6357, US

(21) Appl. No.: 10/704,414

(22) Filed: Nov. 7, 2003

(30) Foreign Application Priority Data
Dec. 17, 2002 (KR) 10-2002-0080757

(51) Int. Cl. H01L 21/302; H01L 21/461

(52) U.S. Cl. 438/689

(57) ABSTRACT

An apparatus and method for manufacturing a semiconductor device are disclosed. An example apparatus for manufacturing a semiconductor device includes an orient chuck configured to secure a wafer, a heating unit configured to preheat the wafer to a predetermined temperature and a process chamber configured to perform etching. The example apparatus also includes a transfer unit configured to transfer the wafer preheated to the predetermined temperature to the process chamber from the orient chuck.

### FIELD OF THE DISCLOSURE

The present disclosure relates generally to an apparatus and method for manufacturing a semiconductor device and, more particularly, to an apparatus and method for manufacturing a semiconductor device that reduces variations in a critical dimension of a wafer during etching.

### BACKGROUND

Extremely precise processes are used in manufacturing a semiconductor device. For example, manufacture of a semiconductor device typically involves depositing a photoresist for forming a semiconductor thin film pattern on a silicon wafer, then exposing and developing the photoresist on semiconductor thin film. In addition, a typical semiconductor manufacturing process includes performing ion injection on the wafer using the patterned photoresist thin film as a mask to inject impurities having a predetermined characteristic, etching a preformed semiconductor thin film to pattern the same, performing deposition to add a predetermined thin film to the wafer, and performing a metal process for connecting a minute thin film circuit pattern.

A semiconductor manufacturing apparatus is usually classified as a wet etch apparatus or a dry etch apparatus depending on the type of etch process used. A plasma processing apparatus that uses plasma gas is an example of a dry etch apparatus.

A plasma processing apparatus typically includes a process chamber inside of which etching is performed. A gas supply unit is mounted in the process chamber and supplies a source gas to the same to create plasma gas. Also, a cathode electrode is mounted in the process chamber. The cathode electrode secures a wafer, and also functions as an electrode. There is also provided a gas spray assembly for uniformly injecting the source gas supplied from the gas supply unit onto the wafer.

Example plasma processing apparatus and plasma processing methods are disclosed in U.S. Pat. Nos. 4,115,184, 6,333,269, 6,392,350, 6,414,280, 6,489,241, and 6,562,720.

Some research is being performed to determine the causes of a reduced yield of semiconductor devices and to find ways to achieve greater integration of semiconductor devices and a larger size of wafers. In particular, in the case of the exposure process and the gate process, which are highly sensitive to the critical dimension, there is continued research with respect to how the critical dimension varies according to wafer temperature.

A method is now being used in which the temperature of the wafer is detected during etching by a temperature sensor mounted thereon. Using this data, information with respect to variations in the critical dimension according to the wafer temperature during actual processes is put in a database to reduce variations in the critical dimension of the wafer.

FIG. 1 is a graph showing changes in wafer temperature as a function of time during a conventional etching process. In FIG. 1, the dashed line extending vertically represents the point of completion of a BARK (bottom anti-reflection coating) etching step, which determines critical dimension in the gate etching process. Further, the various curved trace lines in the graph are formed by connecting actual wafer temperature measurements taken by temperature sensors mounted to wafers.

It is evident from the graph shown in FIG. 1 that at the point where the BARK etching step is completed, the temperatures of the wafers are less than 55° C., that is, less than a temperature of the cathode electrode of the process chamber. This is because etching is performed in a state where the heat of the cathode electrode of the process chamber is transferred to the wafer after the wafer is mounted thereon. As a result, there are significant variations in lot-to-lot or wafer-to-wafer critical dimension in the conventional method.

### BRIEF DESCRIPTION OF THE DRAWINGS

FIG. 1 is a graph of showing changes in wafer temperature as a function of time during a conventional etching process.

FIG. 2 is a schematic view of an example apparatus for manufacturing a semiconductor device.

FIG. 3 is a flow chart depicting an example method for manufacturing a semiconductor device.

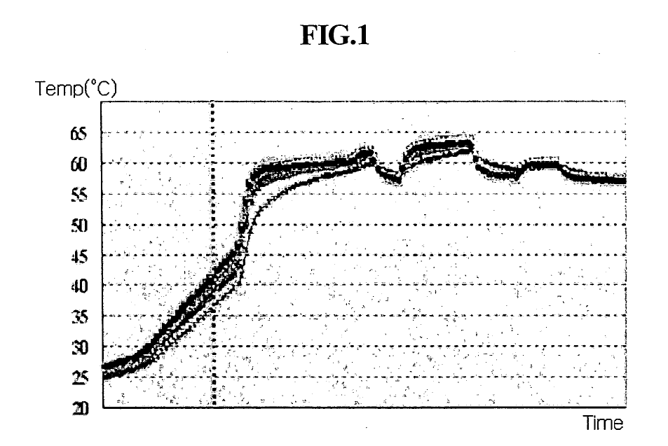

### DETAILED DESCRIPTION

As described in greater detail below, an example apparatus and method for manufacturing a semiconductor device performs etching by loading a wafer into a process chamber after preheating the same to a predetermined temperature so that variations in lot-to-lot or wafer-to-wafer critical dimension are minimized.

In one example, an apparatus for manufacturing a semiconductor device includes an orient chuck on which a wafer is secured; a heating unit for preheating the wafer secured on the orient chuck to a predetermined temperature; a process chamber, at the inside of which etching is performed; and a transfer unit for transferring the wafer preheated to the predetermined temperature to the process chamber from the orient chuck. The orient chuck may be mounted in an orient chamber that is separated from the process chamber. The heating unit may be a heating coil, and may be mounted to the orient chuck. Alternatively, the heating unit may be a halogen lamp that is mounted in the orient chamber.

An example method for manufacturing a semiconductor device includes loading a wafer secured in a cassette on an orient chuck and aligning the wafer; applying heat to the wafer loaded on the orient chuck such that the wafer is preheated to a predetermined temperature; supplying the preheated wafer to a process chamber; and supplying process gas to inside the process chamber and forming a high-pressure environment therein to thereby perform plasma etching. The wafer may be heated to a temperature substantially identical to a temperature of a cathode electrode of the process chamber.

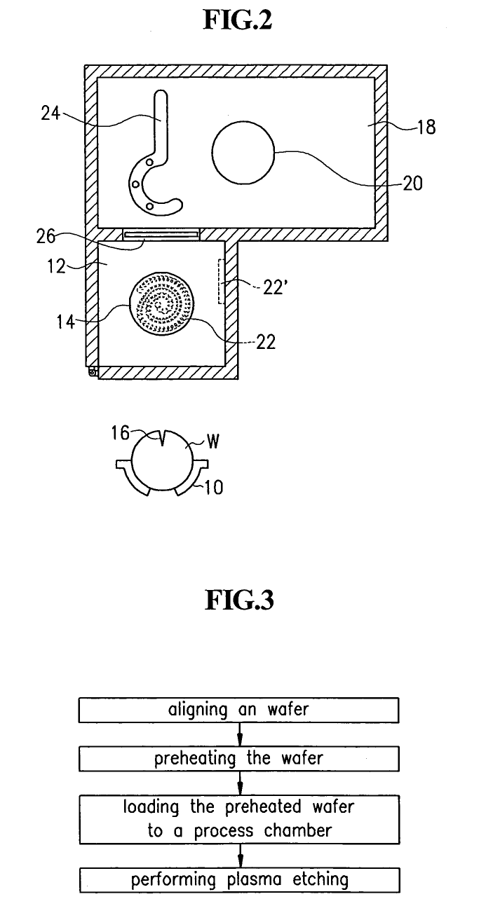

Now tuning in detail to FIGS. 2 and 3, a wafer W secured in a cassette 10 is removed therefrom and loaded on an orient chuck 14 of an orient chamber 12. The wafer W is aligned by a notch 16 to minimize variations in etching characteristics occurring as a result of changes in a direction of the wafer W.

Further, in an aligned state, the wafer W secured on the orient chuck 14 is heated to a predetermined temperature of, for example, a temperature substantially identical to or approximating a temperature of a cathode electrode 20 provided in a process chamber 18. To realize this operation, a heating unit 22 is mounted to the orient chuck 14. As an example of an alternative method to heat the wafer W (in place of the heating unit 22), a halogen lamp 22′ may be mounted in the orient chamber 12.

In FIG. 2, although the orient chuck 14 is shown mounted in the orient chamber 12, which is separated from the process chamber 18, it is also possible to mount the orient chuck 14 directly in the process chamber 18.

With the wafer W heated to the same temperature as the cathode electrode 20 of the process chamber 18, the wafer W is loaded into the process chamber 18 from the orient chamber 12 using a transfer arm 24. Next, process gas for the creation of plasma is injected into the process chamber 18 and power is applied to between the cathode electrode 20 of the process chamber 18 and a body of the chamber to thereby form a high voltage. As a result, the process gas is converted into plasma to thereby perform etching.

Reference numeral 26 in FIG. 2 is a door or slit valve mounted between the orient chamber 12 and the process chamber 18.

If etching is performed in a state where the temperature of the wafer is raised to the temperature of the cathode electrode as described above, lot-to-lot and wafer-to-wafer variances in critical dimension are minimized. Therefore, semiconductor device reliability may be ensured and semiconductor device yield may be improved.

Although certain methods and apparatus have been described herein, the scope of coverage of this patent is not limited thereto. To the contrary, this patent covers all embodiments fairly falling within the scope of the appended claims either literally or under the doctrine of equivalents.

What is claimed is:

1. An apparatus for manufacturing a semiconductor device, comprising:
an orient chuck configured to secure a wafer;
a heating unit configured to preheat the wafer to a predetermined temperature;
a process chamber configured to perform etching; and
a transfer unit configured to transfer the wafer preheated to the predetermined temperature to the process chamber from the orient chuck.

2. An apparatus as defined in claim 1, wherein the orient chuck is mounted in an orient chamber separated from the process chamber.

3. An apparatus as defined in claim 2, wherein the heating unit is a heating coil that is mounted to the orient chuck.

4. An apparatus as defined in claim 2, wherein the heating unit is a halogen lamp that is mounted in the orient chamber.

5. A method for manufacturing a semiconductor device, comprising:
loading a wafer secured in a cassette on an orient chuck;
aligning the wafer;
applying heat to the wafer loaded on the orient chuck such that the wafer is preheated to a predetermined temperature;
supplying the preheated wafer to a process chamber; and
supplying process gas to the process chamber and forming a high-pressure environment therein to perform plasma etching.

6. A method as defined in claim 5, wherein the wafer is heated to a temperature substantially identical to a temperature of a cathode electrode of the process chamber.

7. A method as defined in claim 6, wherein heat is applied to the wafer by a heating coil that is mounted to the orient chuck.

8. A method as defined in claim 6, wherein heat is applied to the wafer by a halogen lamp that is mounted in an orient chamber in which the orient chuck is mounted.
